(19) United States
(12) Patent Application Publication
(10) Pub. No.: US 2026/0144093 A1
(43) Pub. Date: May 21, 2026

(54) SEMICONDUCTOR PACKAGE INCLUDING INTERPOSER HAVING GLASS CORE LAYER

(71) Applicant: Samsung Electronics Co., Ltd., Suwon-si (KR)

(72) Inventor: Hyunjoon Yang, Suwon-si (KR)

(21) Appl. No.: 19/216,983

(22) Filed: May 23, 2025

(30) Foreign Application Priority Data
Nov. 21, 2024 (KR) 10-2024-0167678

(51) Int. Cl. H01L 23/538; H01L 21/48; H01L 23/00; H01L 23/15; H01L 23/498; H01L 25/065; H01L 25/18; H10B 80/00; H10D 80/30

(52) U.S. Cl. CPC H10W 70/611; H10B 80/00; H10D 80/30; H10W 70/05; H10W 70/093; H10W 70/095; H10W 70/65; H10W 70/662; H10W 90/00; H10W 90/401; H10W 90/701; H10W 70/692; H10W 74/15; H10W 90/724; H10W 90/734

(57) ABSTRACT

A semiconductor package according to embodiments of the present inventive concept comprises: a package substrate; an interposer structure on the package substrate; and semiconductor chips on the interposer structure and electrically connected to the package substrate through the interposer structure, wherein the interposer structure comprises: a glass core layer; first through-electrodes penetrating the glass core layer; bridge structures on the first through-electrodes; bridge connection bumps between the bridge structures and the first through-electrodes; and bridge mold layers between the bridge structures and the glass core layer, and covering side surfaces of the bridge connection bumps, wherein each of the bridge structures comprises a base substrate and bridge through-electrodes penetrating the base substrate and vertically overlapping the bridge connection bumps.

### CROSS-REFERENCE TO RELATED APPLICATION(S)

This application claims priority under 35 U.S.C. § 119 to Korean Patent Application No. 10-2024-0167678 filed on Nov. 21, 2024, in the Korean Intellectual Property Office, the disclosure of which is incorporated herein by reference in its entirety.

### BACKGROUND

The present inventive concept relates to a semiconductor package including an interposer having a glass core layer.

Semiconductor devices mounted on electronic devices are required to be miniaturized, as well as to have high performance and high capacity. In order to achieve this, a semiconductor package that interconnects semiconductor chips disposed side by side in a horizontal direction is being developed.

### SUMMARY

In one aspect, a semiconductor package according to the present inventive concept provides a semiconductor package with enhanced reliability.

However, aspects of the present inventive concept are not limited to the previous object, and can be variously extended without departing from the spirit and scope of the present disclosure.

According to an aspect of the present inventive concept, a semiconductor package may be provided, the semiconductor comprising: a package substrate comprising a first core layer and first core through-electrodes penetrating through the first core layer; an interposer structure on the package substrate; semiconductor chips on the interposer structure, and the semiconductor chips electrically connected to the package substrate through the interposer structure; first connection bumps between the semiconductor chips and the interposer structure, and the first connection bumps electrically connecting the semiconductor chips and the interposer structure; second connection bumps between the interposer structure and the package substrate, and the second connection bumps electrically connecting the interposer structure and the package substrate; and third connection bumps below the package substrate, wherein the interposer structure comprises: a second core layer; second core through-electrodes penetrating through the second core layer; third core through-electrodes penetrating through the second core layer and spaced apart from the second core through-electrodes; a bridge structure on the second core through-electrodes; a redistribution structure on the third core through-electrodes; and bridge connection bumps between the at least one bridge structure and the second core through-electrodes, wherein the bridge structure comprises a base substrate and bridge through-electrodes penetrating through the base substrate.

According to an aspect of the present inventive concept, a semiconductor package may be provided, the semiconductor comprising: a package substrate; an interposer structure on the package substrate; and semiconductor chips on the interposer structure, and the semiconductor chips electrically connected to the package substrate through the interposer structure, wherein the interposer structure comprises: a glass core layer; first through-electrodes penetrating through the glass core layer; bridge structures on the first through-electrodes; bridge connection bumps between the bridge structures and the first through-electrodes; and bridge mold layers between the bridge structures and the glass core layer, and covering side surfaces of the bridge connection bumps, wherein each of the bridge structures comprises a base substrate and bridge through-electrodes penetrating through the base substrate and each bridge through-electrode vertically overlapping a respective bridge connection bump.

According to an aspect of the present inventive concept, a semiconductor package may be provided, the semiconductor comprising: a package substrate; an interposer structure on the package substrate; and semiconductor chips on the interposer structure and electrically connected to the package substrate through the interposer structure, wherein the interposer structure comprises: a glass core layer; first through-electrodes penetrating through the glass core layer; second through-electrodes penetrating through the glass core layer and spaced apart from the first through-electrodes; bridge structures with each bridge structure on corresponding first through-electrodes; redistribution structures on with each redistribution structure on corresponding second through-electrodes; bridge connection bumps with each bridge connection bump between a corresponding bridge structure and corresponding first through-electrodes; and bridge mold layers with each bridge mold layer between a corresponding bridge structure and the glass core layer and covering side surfaces of corresponding bridge connection bumps, each of the bridge structures comprises: a base substrate; bridge through-electrodes penetrating the base substrate and each bridge through-electrode vertically overlapping a respective bridge connection bumps; bridge upper pads with each bridge upper pad on a respective bridge through-electrode; and bridge lower pads with each bridge lower pad below a respective bridge through-electrode, and each of the bridge connection bumps are on a lower surface of a respective lower pad and an upper surface of a respective first through-electrodes.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor package according to embodiments of the present inventive concept;

FIG. 2A is a cross-sectional view illustrating an embodiment of the semiconductor package shown in FIG. 1 taken along line I-I′;

FIG. 2B is a cross-sectional view illustrating another embodiment of the semiconductor package shown in FIG. 1 taken along line I-I′;

FIG. 3 is a partial enlarged view of an embodiment of the semiconductor package shown in FIG. 2A;

FIGS. 4A and 4B are partial enlarged views of embodiments of the semiconductor package shown in FIG. 3;

FIG. 5A is a cross-sectional view illustrating another embodiment of the semiconductor package shown in FIG. 1 taken along line I-I′;

FIG. 5B is a cross-sectional view illustrating another embodiment of the semiconductor package shown in FIG. 1 taken along line I-I′;

FIG. 6 is a partial enlarged view of an embodiment of the semiconductor package shown in FIG. 5A;

FIG. 7 is a cross-sectional view showing another embodiment of the semiconductor package shown in FIG. 1 taken along line I-I′;

FIGS. 8 to 11, 12A, 12B, and 13-19 are cross-sectional views illustrating a method for manufacturing a semiconductor package according to an embodiment of the present inventive concept; and

FIGS. 20 to 27 are cross-sectional views illustrating a method for manufacturing a semiconductor package according to another embodiment of the present inventive concept.

### DETAILED DESCRIPTION

Hereinafter, the disclosure will be described with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Items described in the singular herein may be provided in plural, as can be seen, for example, in the drawings. Thus, the description of a single item that is provided in plural should be understood to be applicable to the remaining plurality of items unless context indicates otherwise. The same reference numerals are used for the same components in the drawings and although multiple identical components may be shown, every component may not be individually labeled, and duplicate descriptions for the same components may be omitted.

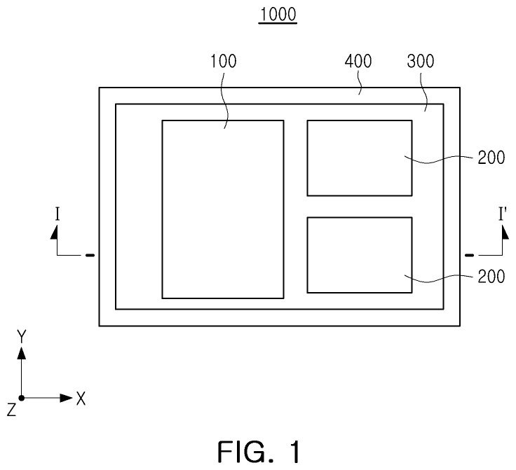

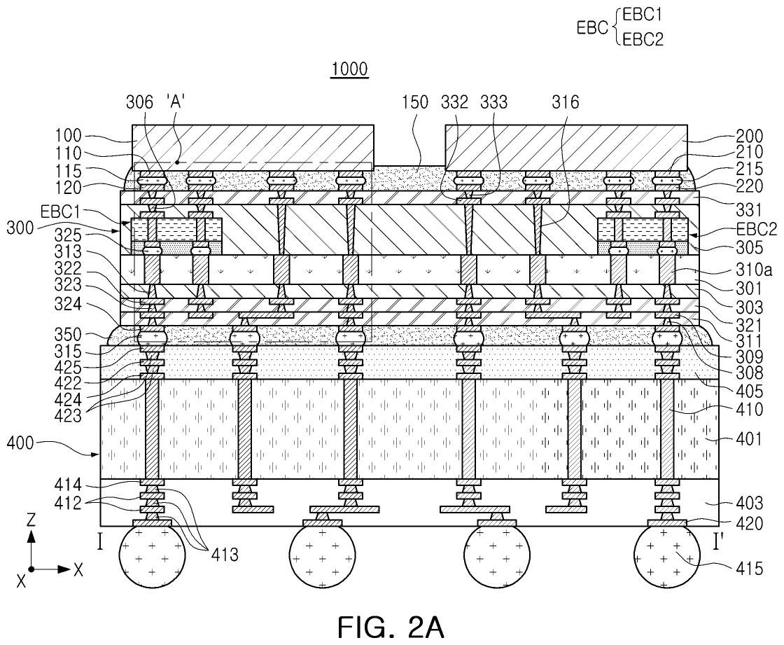

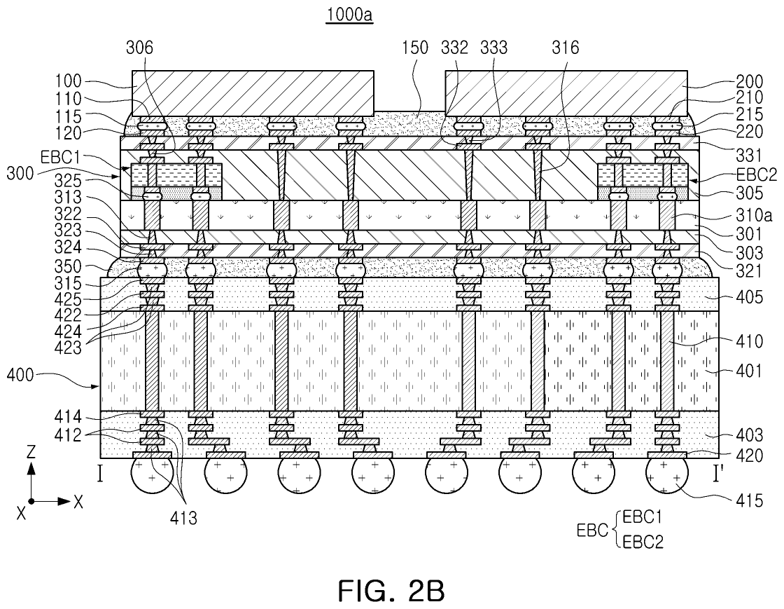

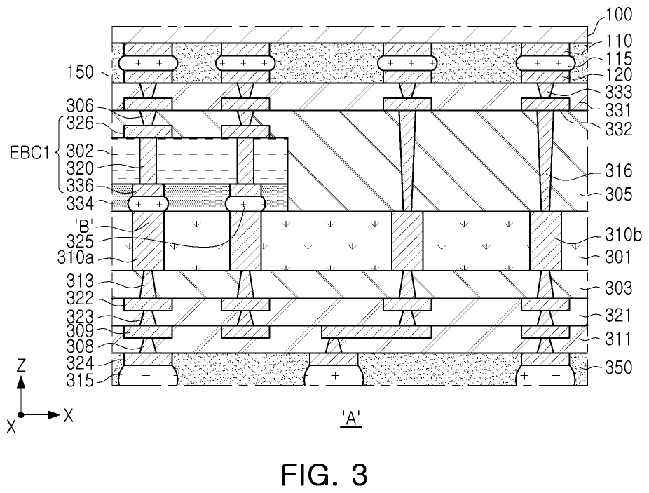

FIG. 1 is a plan view of a semiconductor package according to embodiments of the present inventive concept. FIG. 2A is a cross-sectional view illustrating an embodiment of the semiconductor package shown in FIG. 1 taken along line I-I′. FIG. 2B is a cross-sectional view illustrating another embodiment of the semiconductor package shown in FIG. 1 taken along line I-I′. FIG. 3 is a partial enlarged view of an embodiment of the semiconductor package shown in FIG. 2A. FIG. 3 is an enlarged view of region “A” of the semiconductor package shown in FIG. 2A.

Referring to FIG. 1, FIG. 2A and FIG. 3, the semiconductor package 1000 may include a package substrate 400, an interposer structure 300 on the package substrate 400, and semiconductor chips 100 and 200 on the interposer structure 300.

The package substrate 400 may include a first core layer 401, first core through-electrodes 410 penetrating the first core layer 401, a first lower insulating layer 403 disposed below the first core layer 401, a first upper insulating layer 405 disposed on the first core layer 401, first lower connection pads 420 disposed on a lower surface of the first lower insulating layer 403, and lower connection bumps 415 disposed on lower surfaces of the first lower connection pads 420.

The first core layer 401 may include a resin or glass fiber. The resin may be any one of a phenol resin, an epoxy resin, and a polyimide. In some embodiments, the first core layer 401 may include at least one material selected from a group including Flame Retardant 4(FR 4 ), tetrafunctional epoxy, polyphenylene ether, epoxy/polyphenylene oxide, bismaleimide triazine (BT), thermount, cyanate ester, polyimide, prepreg, Ajinomoto Build-up Film (ABF) of Ajinomoto, and liquid crystal polymer. However, the present inventive concept is not limited thereto, and may include silicon oxide, silicon oxide nitride, silicon nitride, or a combination thereof.

The first core through-electrodes 410 may penetrate the first core layer 401 in a vertical direction (Z-direction). The first core through-electrodes 410 may extend in the vertical direction (Z-direction) and extend from an upper surface to a lower surface of the first core layer 401. An upper surface of the first core through-electrode 410 may be coplanar with the upper surface of the first core layer 401, and a lower surface of the first core through-electrode 410 may be coplanar with the lower surface of the first core layer 401.

The first core through-electrodes 410 may include at least one of conductive materials, such as copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), and graphene.

In an example, a thickness of the first core layer 401 in the vertical direction (Z-direction) may be greater than a thickness of the first lower insulating layer 403 and a thickness of the first upper insulating layer 405.

The first lower insulating layer 403 may be disposed on the lower surface of the first core layer 401. First lower interconnections 412, first lower vias 413, and first intermediate connection pads 414 may be disposed in the first lower insulating layer 403. In an example, each of the first lower vias 413 may be disposed between a pair of the first lower interconnections 412, between a first lower interconnection 412 and a first intermediate connection pad 414, or between a first lower interconnection 412 and a first lower connection pad 420. The first lower interconnections 412 and the first lower vias 413 may electrically connect the first intermediate connection pads 414 and the first lower connection pads 420, respectively. For example, the first lower interconnections 412 and the first lower vias 413 may provide an electrical path for signal and power transmission. The first lower interconnections 412 and the first lower vias 413 may be collectively referred to as a first lower interconnection structure herein.

The first intermediate connection pads 414 may be disposed on an upper surface of the first lower insulating layer 403 and in contact with the lower surface of the first core through-electrodes 410. The first lower connection pads 420 may be disposed on the lower surface of the first lower insulating layer 403.

The first lower interconnections 412, the first lower vias 413, the first intermediate connection pads 414, and the first lower connection pads 420 may include a metal material. The metal material may comprise at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals thereof.

The lower connection bumps 415 may be disposed on the lower surface of the first lower insulating layer 403 and electrically connected to the first lower connection pads 420. In an example, the number of the lower connection bumps 415 may be less than the number of intermediate connection bumps 315 described below.

The first upper insulating layer 405 may be disposed on the upper surface of the first core layer 401. First upper interconnections 422, first upper vias 423, first upper connection pads 424, and second lower connection pads 425 may be disposed in the first upper insulating layer 405. In an example, each of first upper vias 423 may be disposed between pairs of the first upper interconnections 422, between a first upper interconnection 422 and a first upper connection pad 424, or between the first upper interconnection 422 and the second lower connection pad 425, respectively. The first upper interconnections 422 and the first upper vias 423 may electrically connect the first upper connection pads 424 and the second lower connection pads 425. The first upper interconnections 422 and the first upper vias 423 may be collectively referred to as a first upper interconnection structure herein.

The first upper connection pads 424 may be disposed on a lower surface of the first upper insulating layer 405 and may be in contact with the upper surfaces of the first core through-electrodes 410. The second lower connection pads 425 may be disposed on an upper surface of the first upper insulating layer 405, and the intermediate connection bumps 315 may be disposed on upper surfaces of the second lower connection pads 425, respectively. In an example, the first upper interconnections 422, the first upper vias 423, the first upper connection pads 424, and the second lower connection pads 425 may include a metal material.

The first lower insulating layer 403 and the first upper insulating layer 405 may include an insulating material such as silicon oxide or silicon nitride.

The interposer structure 300 may include a second core layer 301, second and third core through-electrodes 310a and 310b penetrating the second core layer 301, a second lower insulating layer 303 disposed below the second core layer 301, a second upper insulating layer 305 disposed on the second core layer 301, a third lower insulating layer 321 disposed below the second lower insulating layer 303, a third upper insulating layer 331 disposed on the second upper insulating layer 305, and a fourth lower insulating layer 311 disposed below the third lower insulating layer 321.

The second core layer 301 may include any one of the materials exemplified in relation to the first core layer 401, excluding a semiconductor material. For example, the second core layer 301 may include a glass substrate mainly composed of SiO₂. In an example, a thickness of the second core layer 301 in the vertical direction (Z-direction) may be less than a thickness of the first core layer 401 in the vertical direction (Z-direction).

The second and third core through-electrodes 310a and 310b may penetrate through the second core layer 301 in the vertical direction (Z-direction). The second and third core through-electrodes 310a and 310b may extend in the vertical direction (Z-direction), and upper surfaces of the second and third core through-electrodes 310a and 310b may be coplanar with an upper surface of the second core layer 301, and lower surfaces of the second and third core through-electrodes 310a and 310b may be coplanar with a lower surface of the second core layer 301. The second and third core through-electrodes 310a and 310b may be spaced apart from each other in a horizontal direction. The second and third core through-electrodes 310a and 310b may be through-glass vias (TGVs).

The second and third core through-electrodes 310a and 310b may include a metal, a metal oxide, a conductive metal nitride, etc. For example, the second and third core through-electrodes 310a and 310b may include copper (Cu), tungsten (W), aluminum (Al), nickel (Ni), cobalt (Co), titanium (Ti), titanium nitride (TiN), etc. In an example, the second and third core through-electrodes 310a and 310b may include copper (Cu). The second and third core through-electrodes 310a and 310b may be formed, for example, by means of electro plating. However, the present inventive concept is not limited thereto, and the second and third core through-electrodes 310a and 310b may be formed by means of a process such as deposition or sputtering.

Herein, the second core layer 301 may be referred to as a “glass core layer,” the second core through-electrode 310a may be referred to as a “first through-electrode,” and the third core through-electrode 310b may be referred to as a “second through-electrode.”

The second lower insulating layer 303 may be disposed on the lower surface of the second core layer 301, and second lower vias 313 may be disposed in the second lower insulating layer 303. The second lower vias 313 may be electrically connected to the second and third core through-electrodes 310a and 310b. The second lower vias 313 may penetrate through the second lower insulating layer 303 in a vertical direction (Z-direction) and contact the lower surfaces of the second and third core through-electrodes 310a and 310b. Each of the second lower vias 313 may have a width that becomes narrower in an upward direction.

The second lower insulating layer 303 may include a material of the group of materials including Ajinomoto Build-up Film (ABF), Benzocyclo-buthene (BCB), photoimageable dielectric (PID), and photosensitive polyimide (PSPI).

The third lower insulating layer 321 may be disposed on a lower surface of the second lower insulating layer 303. Third lower vias 323 and a third lower interconnection layer 322 may be disposed in the third lower insulating layer 321. The third lower interconnection layer 322 may be disposed on an upper surface of the third lower insulating layer 321. The second lower vias 313 in the second lower insulating layer 303 may be disposed between the third lower interconnection layer 322 and the second and third core through-electrodes 310a and 310b, thereby electrically connecting the third lower interconnection layer 322 and the second and third core through-electrodes 310a and 310b.

The third lower vias 323 of the third lower insulating layer 321 may be disposed between the third lower interconnection layer 322 and fourth lower interconnection layers 309 to connect the third lower interconnection layer 322 and the fourth lower interconnection layers 309. The third lower vias 323 may be coplanar with a lower surface of the third lower insulating layer 321. Each of the third lower vias 323 may have a width that becomes narrower in an upward direction.

The fourth lower insulating layer 311 may be disposed on the lower surface of the third lower insulating layer 321. Fourth lower vias 308 and the fourth lower interconnection layers 309 may be disposed in the fourth lower insulating layer 311. The fourth lower interconnection layers 309 may be disposed on an upper surface of the fourth lower insulating layer 311 and connected to the third lower vias 323. The fourth lower vias 308 may be disposed on a lower surface of the fourth lower interconnection layers 309 and connected to the fourth lower interconnection layers 309. The fourth lower vias 308 may be disposed between third lower connection pads 324 disposed on a lower surface of the fourth lower insulating layer 311 and the fourth lower interconnection layers 309 to electrically connect the third lower connection pads 324 and the fourth lower interconnection layers 309. Each of the fourth lower vias 308 may have a width that becomes narrower in an upward direction.

The second lower vias 313, the third lower interconnection layer 322, the third lower vias 323, the fourth lower interconnection layers 309, and the fourth lower vias 308 may be collectively referred to as a second lower interconnection structure herein.

The third lower connection pads 324 may be disposed on the lower surface of the fourth lower insulating layer 311. The fourth lower vias 308 in the fourth lower insulating layer 311 may be in contact with the third lower connection pads 324. The intermediate connection bumps 315 may be disposed on lower surfaces of the third lower connection pads 324. The fourth lower insulating layer 311 may be a solder resist layer. The fourth lower insulating layer 311 may be a protective layer for protecting the fourth lower interconnection layers 309 and the fourth lower vias 308. The fourth lower insulating layer 311 may include a photoresist material.

In an example, the number of the intermediate connection bumps 315 may be less than the numbers of the first and second upper connection bumps 115 and 215. A size of each of the intermediate connection bumps 315 may be less than a size of each of the first and second upper connection bumps 115 and 215.

The interposer structure 300 and the package substrate 400 may be electrically connected through the intermediate connection bumps 315. The intermediate connection bumps 315 may be disposed between the second lower connection pads 425 disposed on an upper surface of the package substrate 400 and the third lower connection pads 324 disposed on a lower surface of the interposer structure 300.

The semiconductor package 1000 may further include a first underfill material layer 350 filling a space between the interposer structure 300 and the package substrate 400 and surrounding side surfaces of the intermediate connection bumps 315 and side surfaces of the third lower connection pads 324.

The second upper insulating layer 305 may be disposed on the upper surface of the second core layer 301. The second upper insulating layer 305 may include the same insulating material as the second lower insulating layer 303. For example, the second upper insulating layer 305 may include a material from the group of materials including Ajinomoto Build-up Film (ABF), Benzocyclo-buthene (BCB), photoimageable dielectric (PID), and photosensitive polyimide (PSPI). However, the present inventive concept is not limited thereto, and the second upper insulating layer 305 may include an insulating material different from that of the second lower insulating layer 303.

Bridge structures EBC, redistribution vias 316, and bridge vias 306 disposed on the bridge structures EBC may be disposed in the second upper insulating layer 305. The bridge structures EBC may be disposed on the second core through-electrodes 310a. The redistribution vias 316 may be disposed on the third core through-electrodes 310b.

Each of the bridge structures EBC may overlap the second core through-electrodes 310a in the vertical direction (Z-direction). The bridge structures EBC may include a first bridge structure EBC1 and a second bridge structure EBC2 spaced apart from the first bridge structure EBC1 in a first direction (X-direction). In an example, the first bridge structure EBC1 may overlap a first semiconductor chip 100 in the vertical direction (Z-direction). The second bridge structure EBC2 may overlap a second semiconductor chip 200 in the vertical direction (Z-direction). The bridge structures EBC illustrated in FIG. 2A are illustrated as including two bridge structures, but are not limited thereto. For example, the bridge structures EBC of the semiconductor package 1000 may include three or more bridge structures.

Each of the first bridge structure EBC1 and the second bridge structure EBC2 may include a base substrate 302, bridge through-electrodes 320 penetrating the base substrate 302, bridge upper pads 326 disposed on an upper surface of the base substrate 302 and overlapping the bridge through-electrodes 320 in the vertical direction (Z-direction), and bridge lower pads 336 disposed on a lower surface of the base substrate 302 and overlapping the bridge through-electrodes 320 in the vertical direction (Z-direction).

Each of the bridge structures may “bridge” electrical connections between adjacent semiconductor chips (e.g., an interconnection die laterally connecting adjacent semiconductor devices). For example, conductive paths within a bridge structure may be electrically connected to multiple semiconductor chips to provide a communication path between the semiconductor chips. The bridge structure may be a bridge chip, a bridge die, or other semiconductor interconnection die.

The base substrate 302 may include a semiconductor element such as silicon and germanium, or a compound semiconductor such as silicon carbide (SiC), gallium arsenide (GaAs), indium arsenide (InAs), and indium phosphide (InP).

The bridge through-electrodes 320 may penetrate the base substrate 302 in the vertical direction (Z-direction), and the bridge through-electrodes 320 may be through silicon vias (TSVs). The bridge through-electrodes 320 may be spaced apart from each other in the horizontal direction. Each of the bridge through-electrodes 320 may include a conductive plug and a barrier film surrounding a side surface of the conductive plug. The conductive plug may include a metal material, such as tungsten (W), titanium (Ti), aluminum (Al), or copper (Cu). The barrier film may include an insulative barrier film and/or a conductive barrier film. The insulative barrier film may be formed of an oxide film, a nitride film, a carbide film, a polymer, or a combination thereof. The conductive barrier film may include a metal compound, such as tungsten nitride (WN), titanium nitride (TiN), or tantalum nitride (TaN).

The bridge lower pads 336 may be disposed on lower surfaces of the bridge through-electrodes 320, and the bridge upper pads 326 may be disposed on upper surfaces of the bridge through-electrodes 320. In an example, a width of each of the bridge upper pads 326 in the first direction (X-direction) may be greater than a width of each of the bridge lower pads 336 in the first direction (X-direction). However, the present inventive concept is not limited thereto, and the width of each of the bridge upper pads 326 in the first direction (X-direction) and may be equal to or less than the width of each of the bridge lower pads 336 in the first direction (X-direction).

In an example, the width of the bridge lower pad 336 in the first direction (X-direction) may be less than a width of the second core through-electrode 310a in the first direction (X-direction). However, the present inventive concept is not limited thereto, and the width of the bridge lower pad 336 in the first direction (X-direction) may be substantially the same as the width of the second core through-electrode 310a in the first direction (X-direction).

The bridge lower pads 336 and the bridge upper pads 326 may include a metal material. The metal material may include a metal from a group including copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals thereof.

The bridge vias 306 may be disposed on the bridge upper pads 326, respectively. In an example, upper surfaces of the bridge vias 306 may be coplanar with an upper surface of the second upper insulating layer 305 and upper surfaces of the redistribution vias 316.

Bridge connection bumps 325 may be disposed on lower surfaces of the bridge lower pads 336. The bridge structures EBC may be electrically connected to the second core through-electrodes 310a through the bridge connection bumps 325. In an example, the bridge connection bumps 325 may be disposed between the bridge lower pads 336 of the bridge structures EBC and the second core through-electrodes 310a. The bridge connection bumps 325 may be in contact with upper surfaces of the second core through-electrodes 310a, respectively.

Bridge mold layers 334 may be disposed in the second upper insulating layer 305. In an example, the bridge mold layers 334 may fill space between the bridge structures EBC and the second core layer 301 and cover side surfaces of the bridge connection bumps 325 and side surfaces of the bridge lower pads 336. The bridge mold layer 334 may have a molded underfill (MUF) structure, but the present inventive concept is not limited thereto. In another embodiment, the bridge mold layer 334 may have a capillary underfill (CUF) structure.

The bridge mold layers 334 may completely overlap the bridge structures EBC in the vertical direction (Z-direction), respectively. However, the present inventive concept is not limited thereto. In another embodiment, the bridge mold layers 334 may cover at least a portion of the respective side surfaces of the bridge structures EBC. In an example, the bridge mold layers 334 may include a thermosetting resin such as an epoxy resin, a thermoplastic resin such as a polyimide, or a prepreg including inorganic fillers and/or glass fibers, ABF, FR-4, BT, and an epoxy molding compound (EMC).

The second upper insulating layer 305 may cover side surfaces of the bridge mold layers 334 and side and upper surfaces of the base substrates 302 of the bridge structures EBC.

The redistribution vias 316 may penetrate through the second upper insulating layer 305 in the vertical direction (Z-direction) and contact the upper surfaces of the third core through-electrodes 310b, respectively. Each of the redistribution vias 316 may have a width that becomes narrower in a downward direction. The redistribution vias 316 may include a metal material. Herein, the second upper insulating layer 305 may be referred to as an “insulating structure,” and the redistribution vias 316 may be referred to as a “redistribution structure.”

The third upper insulating layer 331 may be disposed on the upper surface of the second upper insulating layer 305. Third upper vias 333 and third upper interconnection layers 332 may be disposed in the third upper insulating layer 331. The third upper interconnection layers 332 may be disposed on the bridge vias 306 and the redistribution vias 316. The third upper vias 333 may be disposed on the third upper interconnection layers 332. Each of the third upper vias 333 may have a width narrows in a downward direction. The third upper insulating layer 331 may be a solder resist layer. The third upper insulating layer 331 may be a protective layer for protecting the second upper insulating layer 305, the bridge vias 306 of the second upper insulating layer 305, and the redistribution vias 316. The third upper insulating layer 331 may include a photoresist material.

Fourth lower connection pads 120 and 220 may be disposed on the third upper insulating layer 331. The fourth lower connection pads 120 and 220 may be disposed on the third upper vias 333. The fourth lower connection pads 120 and 220 may include (4-1)-th lower connection pads 120 overlapping the first semiconductor chip 100 in the vertical direction (Z-direction) and (4-2)-th lower connection pads 220 overlapping the second semiconductor chips 200 in the vertical direction (Z-direction).

The semiconductor chips 100 and 200 may be disposed on the interposer structure 300.

The first semiconductor chip 100 may be a logic chip such as a central processor (CPU), a graphic processor (GPU), a field programmable gate array (FPGA), a digital signal processor, an encryption processor, a microprocessor, a microcontroller, an analog-to-digital converter, an ASIC, etc. According to an embodiment, the first semiconductor chip 100 may be referred to as a first semiconductor chip structure.

The second semiconductor chip 200 may be a chip that performs functions the same as or similar to the first semiconductor chip 100, but the present inventive concept is not limited thereto. At least one second semiconductor chip 200 may include a high-capacity memory device, such as a High Bandwidth Memory (HBM). According to an embodiment, the second semiconductor chip 200 may be referred to as a second semiconductor chip structure.

(4-1)-th upper connection pads 110 may be disposed on a lower surface of the first semiconductor chip 100. (4-2)-th upper connection pads 210 may be disposed on a lower surface of the second semiconductor chips 200. The first upper connection bumps 115 may be disposed between the (4-1)-th lower connection pads 120 and the (4-1)-th upper connection pads 110. The second upper connection bumps 215 may be disposed between the (4-2)-th lower connection pads 220 and the (4-2)-th upper connection pads 210.

The interposer structure 300 and the first semiconductor chip 100 may be electrically connected through the first upper connection bumps 115. The interposer structure 300 and the second semiconductor chips 200 may be electrically connected through the second upper connection bumps 215. In an example, the first semiconductor chip 100 may be connected to the package substrate 400 through the redistribution vias 316 and the first bridge structure EBC1 of the interposer structure 300. The second semiconductor chip 200 may be connected to the package substrate 400 through the redistribution vias 316 and the second bridge structure EBC2 of the interposer structure 300.

The first and second upper connection bumps 115 and 215, the intermediate connection bumps 315, and the lower connection bumps 415 may include tin (Sn), indium (In), bismuth (Bi), antimony (Sb), copper (Cu), silver (Ag), zinc (Zn), lead (Pb), and/or alloys thereof. Herein, the upper connection bumps 115 and 215 may be referred to as “first connection bumps,” the intermediate connection bumps 315 may be referred to as “second connection bumps,” and the lower connection bumps 415 may be referred to as “third connection bumps.”

The semiconductor package 1000 may further include a second underfill material layer 150 that fills space between the interposer structure 300 and the first and second semiconductor chips 100 and 200, and covers side surfaces of the first upper connection bumps 115 and side surfaces of the second upper connection bumps 215.

The first underfill material layer 350 and the second underfill material layer 150 may be dispensed and/or formed by a capillary underfill (CUF) process, but the present inventive concept is not limited thereto. The first underfill material layer 350 and the second underfill material layer 150 may include the same material as one another. However, the present inventive concept is not limited thereto, and the first underfill material layer 350 and the second underfill material layer 150 may include different materials.

FIG. 2B illustrates a semiconductor package 1000a as a variation of the semiconductor package 1000 of FIG. 2A, in which the fourth lower insulating layer 311, the fourth lower vias 308, and the fourth lower interconnection layers 309 of the semiconductor package 1000 of FIG. 2A are removed, and the third lower connection pads 324 may be disposed below the third lower insulating layer 321. The third lower vias 323 in the third lower insulating layer 321 of the semiconductor package 1000a may be in contact with the third lower connection pads 324. The lower surface of the third lower insulating layer 321 may be in contact with the first underfill material layer 350. In an example, the first and second upper connection bumps 115 and 215 may overlap the intermediate connection bumps 315 in the vertical direction (Z-direction). In an example, the bridge structure EBC may overlap the first and second upper connection bumps 115 and 215 may be connected to the bridge structure EBC and the intermediate connection bumps 315 in the vertical direction (Z-direction). In an example, the bridge connection bumps 325 may overlap the first and second upper connection bumps 115 and 215 and the intermediate connection bumps 315 in the vertical direction (Z-direction). For example, the first and second upper connection bumps 115 and 215 connected to the bridge structure EBC and the intermediate connection bumps 315 may be disposed on a straight line extending in the vertical direction (Z-direction) together with the bridge connection bumps 325.

Herein, the vertical direction (Z-direction) is a direction substantially perpendicular or perpendicular to an upper surface of the package substrate 400, and the first direction (X-direction) and a second direction (Y-direction) may be referred to as horizontal directions, and the horizontal directions may be parallel to the upper surface of the package substrate 400.

The semiconductor package 1000 according to the present embodiments may include a package substrate 400, an interposer structure 300 on the package substrate 400, and semiconductor chips 100 and 200 on the interposer structure 300, and the interposer structure 300 may include a glass core layer 301, bridge structures EBC including bridge through-electrodes 320 that are through-silicon vias on the glass core layer 301, and a redistribution structure 316 on the glass core layer 301. Accordingly, the semiconductor package 1000 with improved electrical performance may be provided.

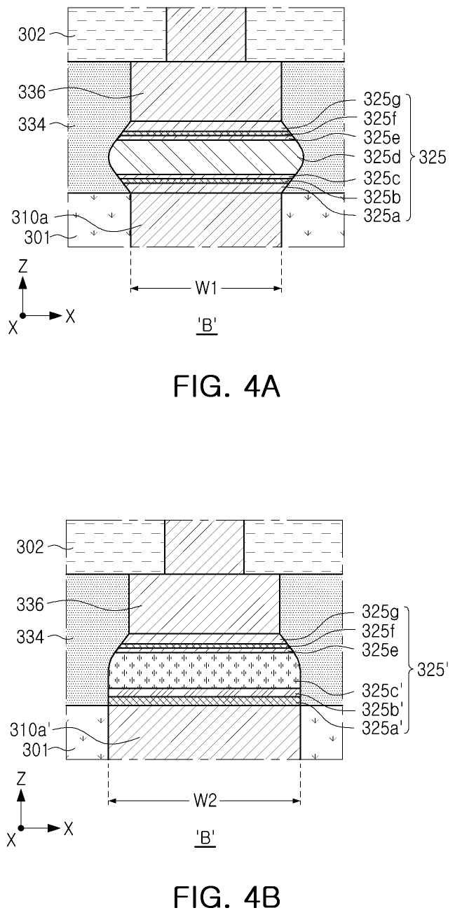

FIGS. 4A and 4B are partial enlarged views of embodiments of the semiconductor package shown in FIG. 3. FIGS. 4A and 4B are enlarged views of region “B” of the semiconductor package illustrated in FIG. 3.

Referring to FIG. 4A, the bridge connection bump 325 may be disposed between the second core through-electrode 310a and the bridge lower pad 336. A lower surface of the bridge connection bump 325 may be in contact with an upper surface of the second core through-electrode 310a, and an upper surface of the bridge connection bump 325 may be in contact with a lower surface of the bridge lower pad 336. The second core through-electrode 310a may have a diameter (or width) having a first size W1. The first size W1 may be about 90 μm or less. The bridge connection bump 325 may include a plurality of conductive layers 325a to 325g. In an example, the plurality of conductive layers 325a to 325g may include a first conductive layer 325a, a second conductive layer 325b, a third conductive layer 325c, a fourth conductive layer 325d, a fifth conductive layer 325e, a sixth conductive layer 325f, and a seventh conductive layer 325g that are sequentially disposed on the upper surface of the first core through-electrode 310a. An upper surface of the second core through-electrode 310a may be in contact with the first conductive layer 325a, and the lower surface of the bridge lower pad 336 may be in contact with the seventh conductive layer 325g. For example, the first conductive layer 325a, the third conductive layer 325c, the fifth conductive layer 325e, and the seventh conductive layer 325g may include copper (Cu), the second conductive layer 325b and the sixth conductive layer 325f may include nickel (Ni), and the fourth conductive layer 325d may include a tin-silver (SnAg) alloy. An interface between the first conductive layer 325a and the second core through-electrode 310a may be indistinguishable.

In an example, a thickness of each of the first conductive layer 325a and the seventh conductive layer 325g in the vertical direction (Z-direction) may be greater than a thickness of each of the second, third, fifth, and sixth conductive layers 325b, 325c, 325e and 325f in the vertical direction (Z-direction), and may be less than a thickness of the fourth conductive layer 325d in the vertical direction (Z-direction).

Referring to FIG. 4B, a bridge connection bump 325′ may be disposed between the second core through-electrode 310a and the bridge lower pad 336. A lower surface of the bridge connection bump 325′ may be in contact with the upper surface of the second core through-electrode 310a′, and an upper surface of the bridge connection bump 325′ may be in contact with the lower surface of the bridge lower pad 336. The second core through-electrode 310a′ may have a diameter having a second size W2. The second size W2 may be greater than about 90 μm and less than or equal to about 130 μm. The bridge connection bump 325′ may include first to sixth conductive layers 325a′, 325b′, 325c′, 325e, 325f and 325g. In an example, the first to sixth conductive layers 325a′, 325b′, 325c′, 325e, 325f and 325g may be sequentially disposed on the upper surface of the first core through-electrode 310a. The first conductive layer 325a′ may be in contact with the upper surface of the second core through-electrode 310a′, and the sixth conductive layer 325g may be in contact an upper surface of the bridge lower pad 336. For example, the first conductive layer 325a′ may include nickel (Ni), the second conductive layer 325b′ may include gold (Au), and the third conductive layer 325c′ may include micro balls and/or a tin-silver (Sn—Ag) alloy. The fourth conductive layer 325e and the sixth conductive layer 325g may include copper (Cu), and the fifth conductive layer 325f may include nickel (Ni). The fourth, fifth, and sixth conductive layers 325e, 325f and 325g of the bridge connection bump 325′ may correspond to the fifth, sixth, and seventh conductive layers 325e, 325f and 325g of the bridge connection bump 325 of FIG. 4A.

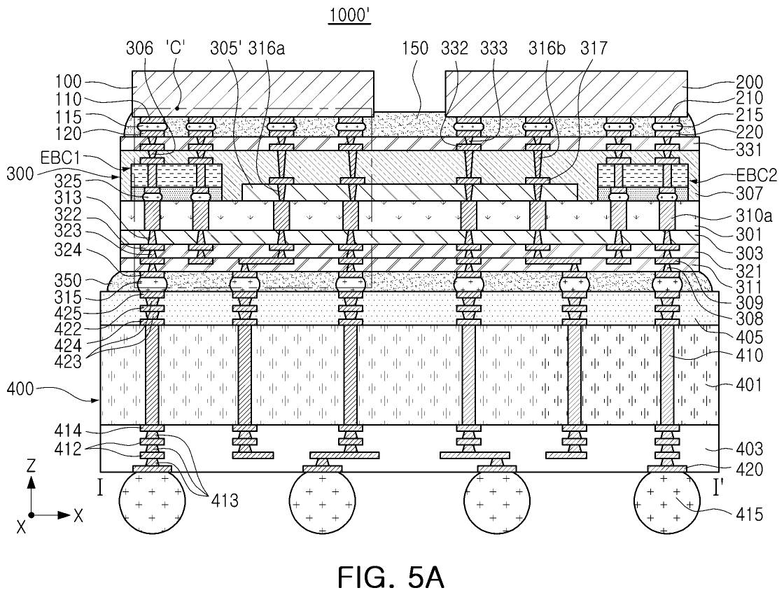

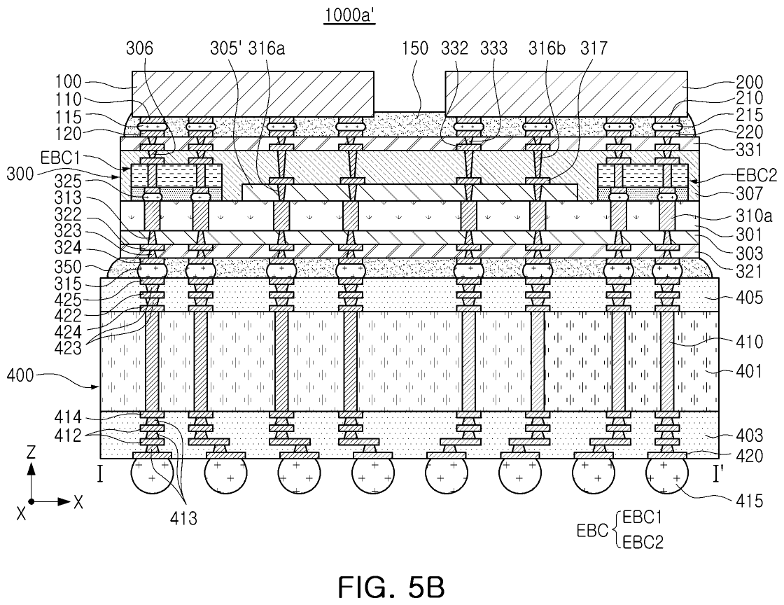

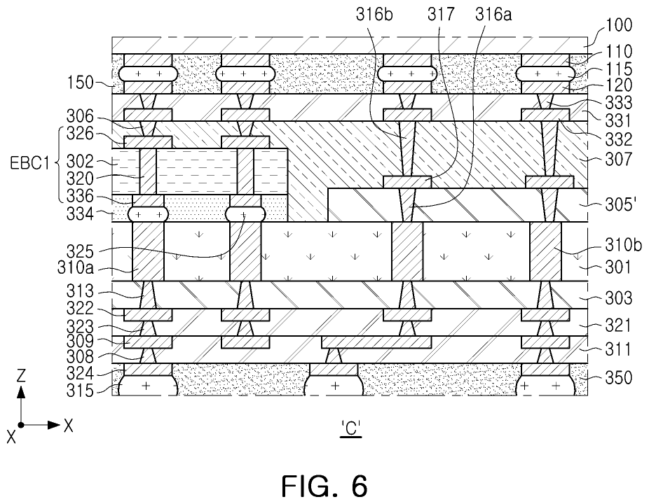

FIG. 5A is a cross-sectional view illustrating another embodiment of the semiconductor package shown in FIG. 1 taken along line I-I′. FIG. 5B is a cross-sectional view illustrating another embodiment of the semiconductor package shown in FIG. 1 taken along line I-I′. FIG. 6 is a partial enlarged view of an embodiment of the semiconductor package shown in FIG. 5A. FIG. 6 is an enlarged view of region “C” of the semiconductor package shown in FIG. 5A.

Referring to FIGS. 5A and 6, a semiconductor package 1000′ may include a (2-1-th upper insulating layer 305′ disposed on a second core layer 301 and a (2-2)-th upper insulating layer 307 covering side and upper surfaces of the (2-1)-th upper insulating layer 305′. The semiconductor package 1000′ may include first vias 316a penetrating through the (2-1)-th upper insulating layer 305′ and connected to a third core through-electrodes 310b, first interconnection layers 317 disposed on the (2-1)-th upper insulating layer 305′ and connected to the first vias 316a, and second vias 316b on a first interconnection layers 317. Except for the (2-1)-th upper insulating layer 305′, the (2-2)-th upper insulating layer 307, the first and second vias 316a and 316b, and the first interconnection layers 317, the remaining configurations illustrated in FIG. 5A and FIG. 6 may be identical to or substantially the same as the configurations illustrated in FIG. 2A.

The (2-1)-th upper insulating layer 305′ may be disposed on the second core layer 301 and cover the third core through-electrodes 310b. The (2-2)-th upper insulating layer 307 may be disposed on the second core layer 301 and cover side and upper surfaces of the (2-1)-th upper insulating layer 305′.

The first vias 316a may penetrate the (2-1)-th upper insulating layer 305′ and be electrically connected to the third core through-electrodes 310b, respectively. The first interconnection layers 317 may be disposed on the (2-1)-th upper insulating layer 305′ and connected to the first vias 316a, respectively. The second vias 316b may be disposed on the first interconnection layers 317, respectively. Side and upper surfaces of the first interconnection layers 317 and side surfaces of the second vias 316b may be covered by the (2-2)-th upper insulating layer 307. The first and second vias 316a and 316b and the first interconnection layers 317 may be collectively referred to as a “redistribution structure” herein.

An upper surface of the (2-1)-th upper insulating layer 305′ may be disposed at a level lower than an upper surface of the bridge structures EBC. The (2-2)-th upper insulating layer 307 may be in contact with a side surface of a bridge mold layers 334 and side and upper surfaces of a base substrate 302 of the bridge structure EBC. The upper surface of the (2-2)-th upper insulating layer 307, the upper surface of the bridge vias 306, and the upper surface of the second vias 316b may be coplanar.

The (2-1)-th upper insulating layer 305′ may include a first insulating material, and the (2-2)-th upper insulating layer 307 may include a second insulating material different from the first insulating material. The first insulating material may include at least one material from a group including Ajinomoto Build-up Film (ABF), Benzocyclo-buthene (BCB), photoimageable dielectric (PID), and photosensitive polyimide (PSPI). The second insulating material may include silicon oxide or silicon nitride. However, the present inventive concept is not limited thereto, and in another embodiment, the (2-1)-th upper insulating layer 305′ may include the same insulating material as the (2-2)-th upper insulating layer 307. For example, the (2-1)-th upper insulating layer 305′ and the (2-2)-th upper insulating layer 307 may include Ajinomoto Build-up Film (ABF).

FIG. 5B illustrate a semiconductor package 1000a′ as a variation of the semiconductor package 1000′ of FIG. 5A, in which the fourth lower insulating layer 311, the fourth lower vias 308, and the fourth lower interconnection layers 309 are removed, and a third lower connection pads 324 may be disposed below the third lower insulating layer 321.

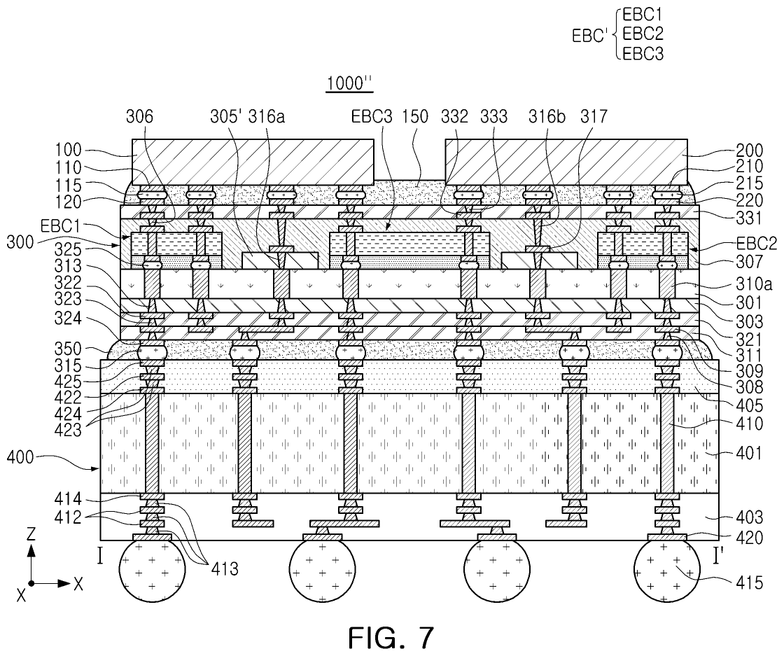

FIG. 7 is a cross-sectional view showing another embodiment of the semiconductor package shown in FIG. 1 taken along line I-I′.

Referring to FIG. 7, a semiconductor package 1000″ may include bridge structures EBC′. The remaining configurations illustrated in FIG. 7, except for the bridge structures EBC′, may be identical to or substantially the same as the configurations illustrated in FIG. 5A.

The bridge structures EBC′ may include a first bridge structure EBC1, a second bridge structure EBC2, and a third bridge structure EBC3 disposed between the first bridge structure EBC1 and the second bridge structure EBC2. The third bridge structure EBC3 may be disposed in a lower region between a first semiconductor chip 100 and a second semiconductor chip 200 (e.g., the third bridge structure EBC3 may vertically overlap a gap between the first semiconductor chip 100 and the second semiconductor chip 200). The third bridge structure EBC3 may be electrically connected to the first semiconductor chip 100 and the second semiconductor chip 200. The third bridge structure EBC3 may be disposed at the same level as the first and second bridge structures EBC1 and EBC2 between the first and second bridge structures EBC1 and EBC2.

The third bridge structure EBC3 may be connected to a (4-1)-th lower connection pad 120 through bridge vias 306 to be connected to the first semiconductor chip 100, and may be connected to a (4-2)-th lower connection pad 220 through the bridge vias 306 so as to be connected to the second semiconductor chip 200.

A (2-1)-th upper insulating layers 305′ may be disposed between the first bridge structure EBC1 and the second bridge structure EBC2 and between the second bridge structure EBC2 and the third bridge structure EBC3. Redistribution structures 316a, 316b and 317 may be disposed between the first bridge structure EBC1 and the second bridge structure EBC2 and between the second bridge structure EBC2 and the third bridge structure EBC3. A (2-2)-th upper insulating layer 307 may cover side and upper surfaces of the (2-1)-th upper insulating layers 305′ and be in contact with side surfaces and upper surfaces of the bridge structures EBC′.

In another embodiment, the fourth lower insulating layer 311, the fourth lower vias 308, and the fourth lower interconnection layers 309 may be removed in the semiconductor package 1000″, and third lower connecting pads 324 may be disposed below the third lower insulating layer 321.

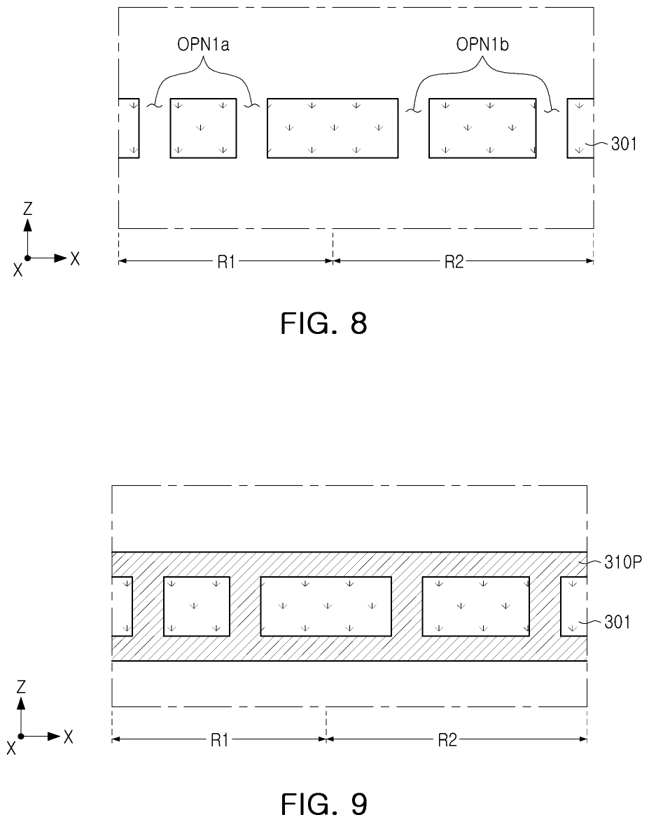

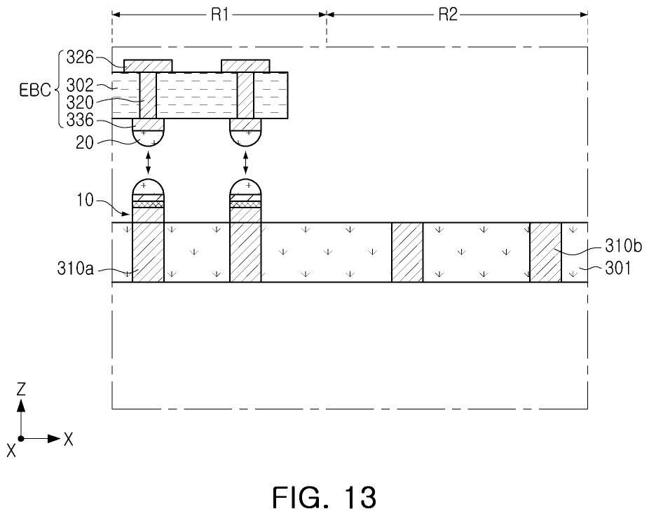

FIGS. 8 to 19 are cross-sectional views illustrating a method for manufacturing a semiconductor package according to an embodiment of the present inventive concept. FIGS. 8 to 12B are cross-sectional views schematically illustrating a manufacturing process for a glass core layer on one surface of which a first solder ball is formed in the method for manufacturing the semiconductor package, and FIGS. 13 to 19 are cross-sectional views schematically illustrating a manufacturing process for an interposer structure of the semiconductor package of FIG. 2A that is performed after the manufacturing process for the glass core layer described with reference to FIGS. 8 to 12A.

Referring to FIG. 8, after preparing a glass core layer 301, the method may include an operation of forming first openings OPN1a and OPN1b penetrating the glass core layer 301 for forming through-electrodes. In an example, the glass core layer 301 may include a first region R1 and a second region R2. The first region R1 may define a region in which the bridge structure EBC of FIG. 2A is disposed. The second region R2 may define a region in which the redistribution structure of FIG. 2A (e.g., the redistribution vias 316 of FIG. 2A) is formed. The first openings OPN1a and OPN1b may include (1-1)-th openings OPN1a formed in the first region R1 and (1-2)-th openings OPN1b formed in the second region R2. Sizes of the first openings OPN1a and OPN1b may be the same, but the present inventive concept is not limited thereto, and the sizes of the (1-1)-th opening OPN1a and the (1-2)-th opening OPN1b may be different from each other. The first openings OPN1a and OPN1b may be formed by means of a laser drilling process or an etching process.

Referring to FIG. 9, the method may include an operation of forming a through-electrode metal layer 310P filling the first openings OPN1a and OPN1b. A process of forming a separate seed metal may be performed before the operation of forming the through-electrode metal layer 310P. The through-electrode metal layer 310P may fill the first openings OPN1a and OPN1b and be formed on upper and lower surfaces of the glass core layer 301. The through-electrode metal layer 310P may include copper (Cu).

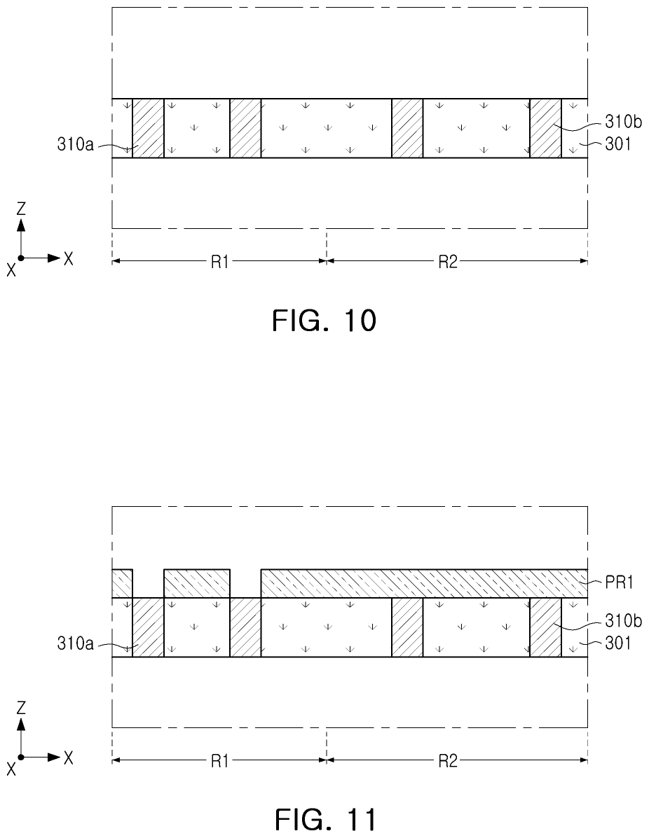

Referring to FIG. 10, the through-electrode metal layer 310P on the upper and lower surfaces of the glass core layer 301 may be removed by means of a grinding or polishing process to form first through-electrodes 310a in the first region R1 and second through-electrodes 310b in the second region R2.

Referring to FIG. 11, a first photoresist pattern PR1 exposing an upper surface of the first through-electrodes 310a formed in the first region R1 on the glass core layer 301 and covering the second region R2 may be formed on the glass core layer 301.

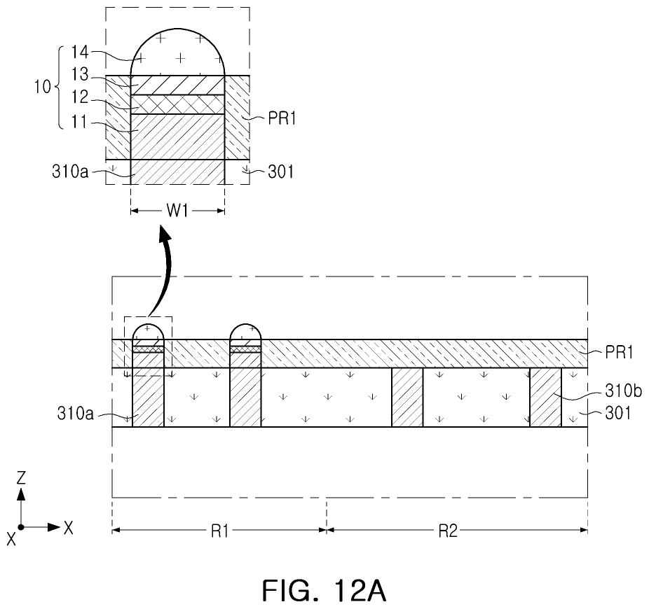

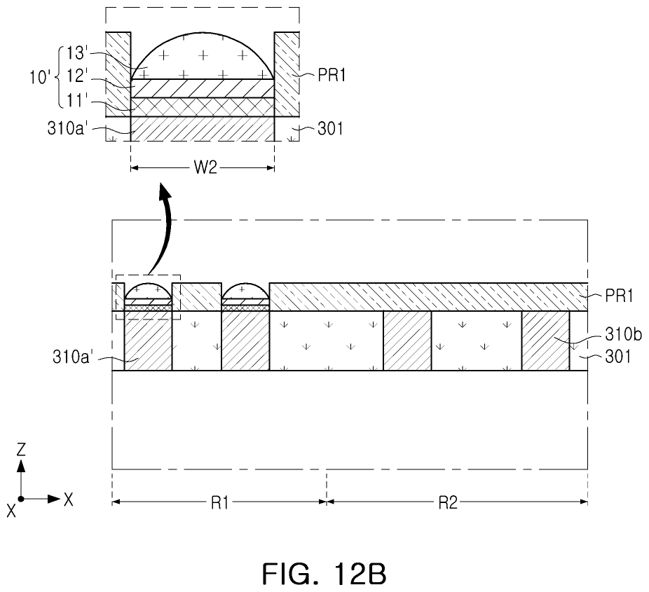

Referring to FIG. 12A, when a width of each of the first through-electrodes 310a exposed through the first photoresist pattern PR1 has a first size W1, first solder balls 10 may be formed on upper surfaces of the first through-electrodes 310a, respectively. The first size W1 may be about 90 μm or less. The first solder ball 10 may include first to fourth conductive layers 11 to 14. For example, the first conductive layer 11 and the third conductive layer 13 may include copper (Cu), the second conductive layer 12 may include nickel (Ni), and the fourth conductive layer 14 may include an alloy of tin-silver (SnAg). Since the first through-electrode 310a and the first conductive layer 11 include copper (Cu), an interface of a joint surface of the first through-electrode 310a and the first conductive layer 11 may not be distinguishable.

A thickness of the first conductive layer 11 in a vertical direction (Z-direction) may be about 8 μm. A thickness of the second conductive layer 12 in the vertical direction (Z-direction) may be about 3 μm. A thickness of the third conductive layer 13 in the vertical direction (Z-direction) may be about 3 μm. A thickness of the fourth conductive layer 14 in the vertical direction (Z-direction) may be about 21 μm. After forming the first solder balls 10, the first photoresist pattern PR1 may be removed.

Referring to FIG. 12B, when a width of each of the first through-electrodes 310a′ exposed through the first photoresist pattern PR1 has a second size W2, first solder balls 10′ may be formed on the upper surfaces of the first through-electrodes 310a, respectively. The second size W2 may be greater than about 90 μm and less than or equal to about 130 μm. The first solder ball 10′ may include first to third conductive layers 11′ to 13′. For example, the first conductive layer 11′ may include nickel (Ni), the second conductive layer 12′ may include gold (Au), and the third conductive layer 13′ may include micro balls. In an example, a height of the first conductive layer 11′ in a vertical direction (Z-direction) may be about 3 μm. A height of the second conductive layer 12′ in the vertical direction (Z-direction) may be about 0.3 μm. The height of the third conductive layer 12′ in the vertical direction (Z-direction) may be about 20 μm.

After the processes of forming the first solder balls 10 and 10′ of FIGS. 12A and 12B, the glass core layer 301 of FIGS. 8 to 12B may include a plurality of glass core layers, so the plurality of glass core layers may be separated into individual glass core layers by means of a sawing process.

Referring to FIG. 13, the method may include an operation of disposing a preformed bridge structure EBC on the first through-electrodes 310a of the first region R1, and an operation of performing a reflow process for soldering the first solder balls 10 formed on the first through-electrodes 310a and second solder balls 20 formed on lower surfaces of bridge lower pads 336 of the bridge structure EBC. The bridge structure EBC may include a base substrate 302, bridge through-electrodes 320 penetrating the base substrate 302, bridge upper pads 326 disposed on the bridge through-electrodes 320, and bridge lower pads 336 disposed on lower surfaces of the bridge through-electrodes 320. In an example, the second solder ball 20 may have the same structure as the first solder ball 10. In an example, the first conductive layer 11, the second conductive layer 12, the third conductive layer 13, and the fourth conductive layer 14 of FIG. 12A may be sequentially formed on each of the lower surfaces of the bridge lower pads 336.

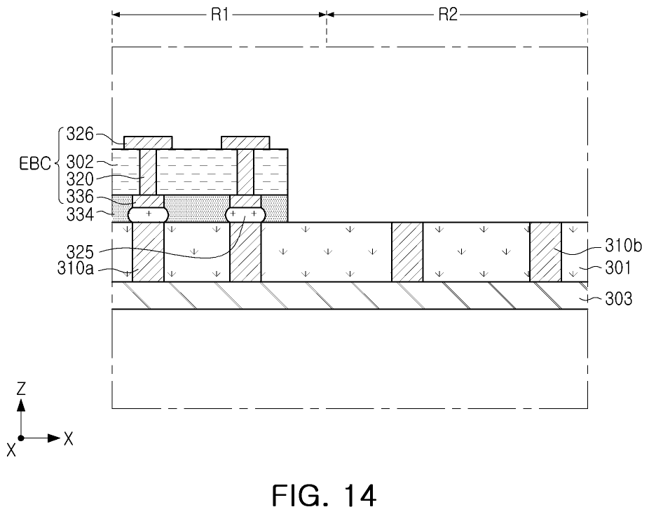

Referring to FIG. 14, by combining the first solder balls 10 formed on the first through-electrodes 310a of the glass core layer 301 and the second solder balls 20 formed on the lower surfaces of the bridge lower pads 336 of the bridge structure EBC, bridge connection bumps 325 connecting the glass core layer 301 and the bridge structure EBC may be formed. The method may include an operation of forming a bridge mold layer 334 filling a space between the glass core layer 301 and the bridge structure EBC and covering side surfaces of the bridge connection bumps 325.

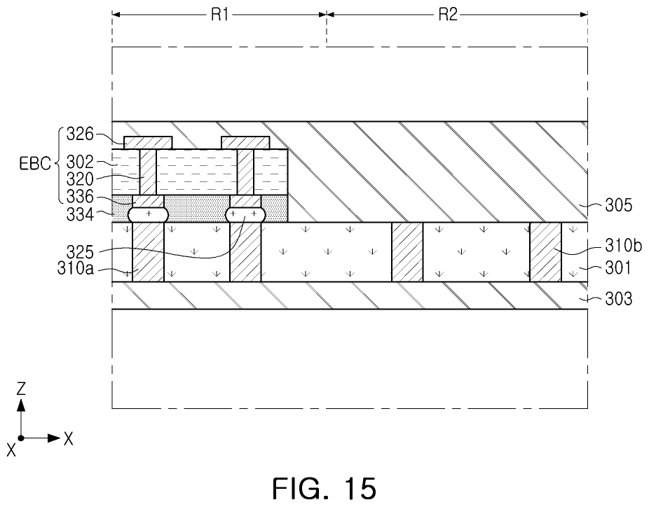

Referring to FIG. 15, a second upper insulating layer 305 may be formed on the upper surface of the glass core layer 301, and a second lower insulating layer 303 may be formed on the lower surface of the glass core layer 301. The second upper insulating layer 305 may cover an upper surface of the second through-electrodes 310b of the second region R2 on the upper surface of the glass core layer 301, and cover side and upper surfaces of the bridge structure EBC and a side surface of the bridge mold layer 334. In an example, the second lower insulating layer 303 may cover lower surfaces of the first and second through-electrodes 310a and 310b on the lower surface of the glass core layer 301. The second upper insulating layer 305 and the second lower insulating layer 303 may include Ajinomoto Build-up Film (ABF).

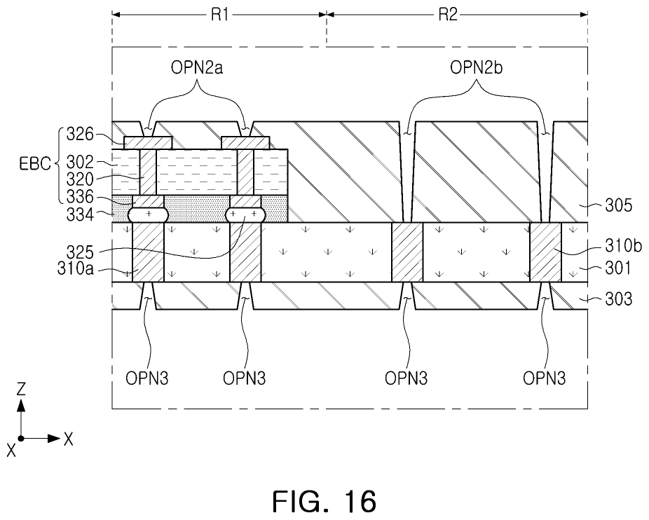

Referring to FIG. 16, the method may include an operation of forming second openings OPN2a and OPN2b penetrating through the second upper insulating layer 305, and an operation of forming third openings OPN3 penetrating through the second lower insulating layer 303 to expose the lower surfaces of the first and second through-electrodes 310a and 310b. The second openings OPN2a and OPN2b may penetrate through the second upper insulating layer 305 and include (2-1)-th openings OPN2a exposing upper surfaces of the bridge upper pads 326 of the bridge structure EBC and (2-2)-th openings OPN2b exposing upper surfaces of the second through-electrodes 310b. In an example, each of the second openings OPN2a and OPN2b may have a width that narrows in a downward direction, and each of the third openings OPN3 may have a width that narrows in an upward direction. The second openings OPN2a and OPN2b and the third openings OPN3 may be formed by means of a laser drilling process or an etching process.

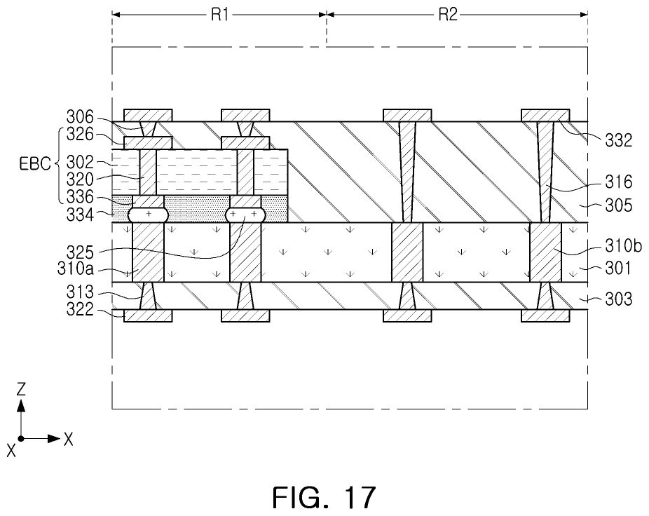

Referring to FIG. 17, in the first region R1, the (2-1-th openings OPN2a of FIG. 16 may be filled with a conductive material to form bridge vias 306, and in the second region R2, the second-second openings OPN2b of FIG. 16 may be filled with a conductive material to form redistribution vias 316. The third openings OPN3 of FIG. 16 may be filled with a conductive material to form second lower vias 313. Upper surfaces of the redistribution vias 316 may be coplanar with upper surfaces of the bridge vias 306.

After forming the bridge vias 306 and the redistribution vias 316, third upper interconnection layers 332 connected to the bridge vias 306 and the redistribution vias 316 may be formed on the second upper insulating layer 305. After forming the second lower vias 313, third lower interconnection layer 322 overlapping the second lower vias 313 may be formed below the second lower insulating layer 303.

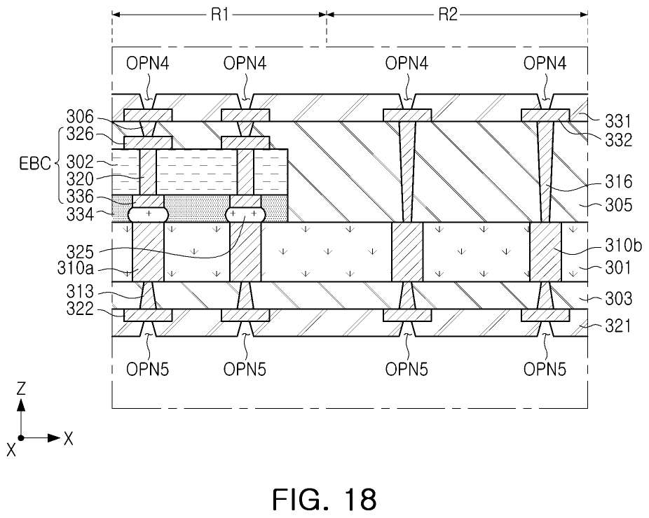

Referring to FIG. 18, a third upper insulating layer 331 covering the third upper interconnection layers 332 may be formed on the second upper insulating layer 305, and a third lower insulating layer 321 covering the third lower interconnection layer 322 may be formed below the second lower insulating layer 303. Fourth openings OPN4 penetrating the third upper insulating layer 331 and exposing upper surfaces of the third upper interconnection layers 332 may be formed, and fifth openings OPN5 penetrating the third lower insulating layer 321 and exposing lower surfaces of the third lower interconnection layer 322 may be formed. The third lower insulating layer 321 and the third upper insulating layer 331 may be solder resist layers, and may be formed by applying and drying a liquid photoresist (LPR) or laminating a dry film photoresist (DFR) at a certain pressure.

The fourth openings OPN4 and the fifth openings OPN5 may be formed by means of a laser drilling process or an etching process.

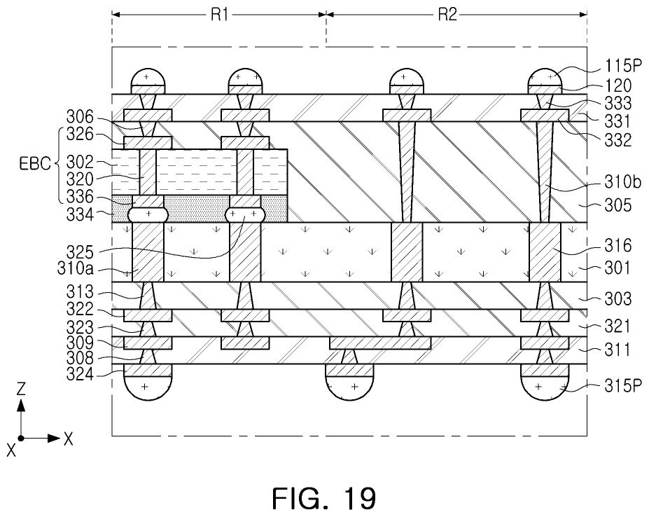

Referring to FIG. 19, the fourth openings OPN4 of FIG. 18 may be filled with a conductive material to form third upper vias 333, and the fifth openings OPN5 may be filled with a conductive material to form third lower vias 323. Fourth lower interconnection layers 309 may be formed below the third lower vias 323. After forming the fourth lower interconnection layers 309, openings may be formed to expose lower surfaces of the fourth lower interconnection layers 309 by penetrating through the fourth lower insulating layer 311, and then a conductive material may be filled to form fourth lower vias 308. Thereafter, third lower connection pads 324 may be formed on lower surfaces of the fourth lower vias 308, and lower solder balls 315P may be formed on lower surfaces of the third lower connection pads 324.

Fourth lower connection pads 120 may be formed on the third upper vias 333, and upper solder balls 115P may be formed on the fourth lower connection pads 120. In an example, a size of each of the upper solder balls 115P may be less than a size of each of the lower solder balls 315P.

Next, referring to FIG. 2A and FIG. 19, the package substrate 400 may be combined therewith through the lower solder balls 315P, and the semiconductor chips 100 and 200 may be combined therewith through the upper solder balls 115P. Accordingly, the semiconductor package 1000 may be manufactured.

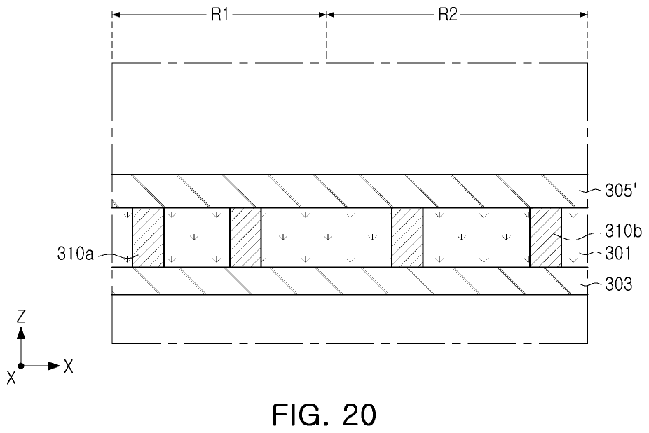

FIGS. 20 to 27 are cross-sectional views illustrating a method for manufacturing a semiconductor package according to another embodiment of the present inventive concept. FIGS. 20 to 27 are cross-sectional views schematically illustrating a manufacturing process of the interposer structure of the semiconductor package of FIG. 2A performed after the manufacturing process for the glass core layer described with reference to FIGS. 8 to 12A.

Referring to FIG. 20, a (2-1-th upper insulating layer 305′ may be formed on the upper surface of the glass core layer 301, and a second lower insulating layer 303 may be formed on the lower surface of the glass core layer 301. The (2-1)-th upper insulating layer 305′ may be in contact with the upper surface of the glass core layer 301 and cover the upper surfaces of the first and second through-electrodes 310a and 310b, and the (2-1)-th lower insulating layer 303 may be in contact with the lower surface of the glass core layer 301 and cover the lower surfaces of the first and second through-electrodes 310a and 310b. The (2-1)-th upper insulating layer 305′ and the (2-1)-th lower insulating layer 303 may include Ajinomoto Build-up Film (ABF).

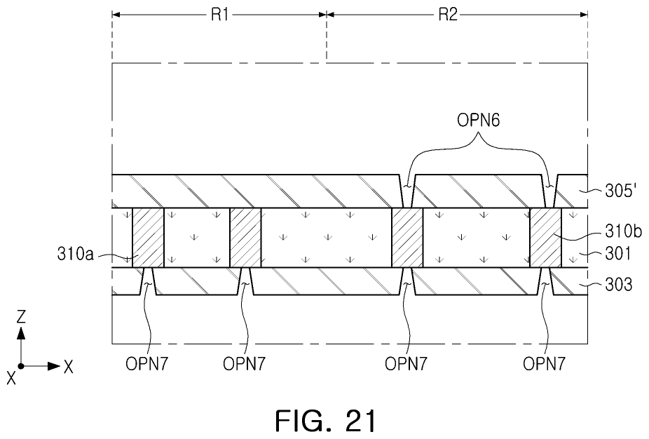

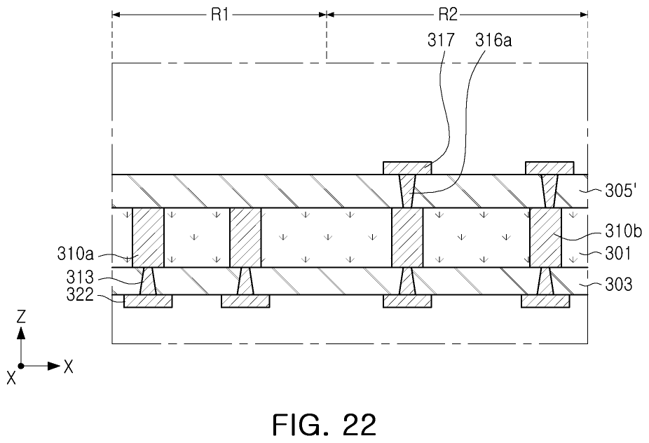

Referring to FIG. 21, the method may include an operation of forming sixth openings OPN6 penetrating the (2-1)-th upper insulating layer 305′ to expose the upper surface of the second through-electrodes 310b, and seventh openings OPN7 penetrating the second lower insulating layer 303 to expose the lower surface of the first and second through-electrodes 310a and 310b.

Referring to FIG. 22, in the second region R2, first vias 316a may be formed by filling the sixth openings OPN6 of FIG. 21 with a conductive material, and second lower vias 313 may be formed by filling the seventh openings OPN7 of FIG. 21 with the conductive material. After forming the first vias 316a, first interconnection layers 317 overlapping the first vias 316a may be formed on the (2-1)-th upper insulating layer 305′, and after forming the second lower vias 313, third lower interconnection layer 322 overlapping the second lower vias 313 may be formed on a lower surface of the second lower insulating layer 303.

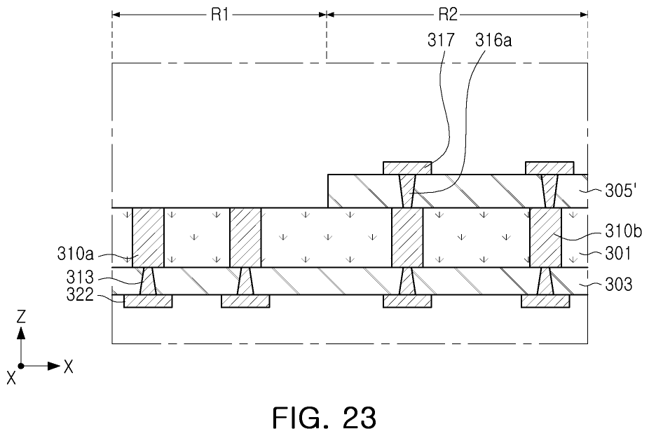

Referring to FIG. 23, the (2-1)-th upper insulating layer 305′ covering the glass core layer 301 in the first region R1 may be removed. A mask (not shown) may be placed on the (2-1)-th upper insulating layer 305′ disposed in the second region R2, and exposure light may be applied, and development may be performed to remove the (2-1)-th upper insulating layer 305′ disposed in the first region R1.

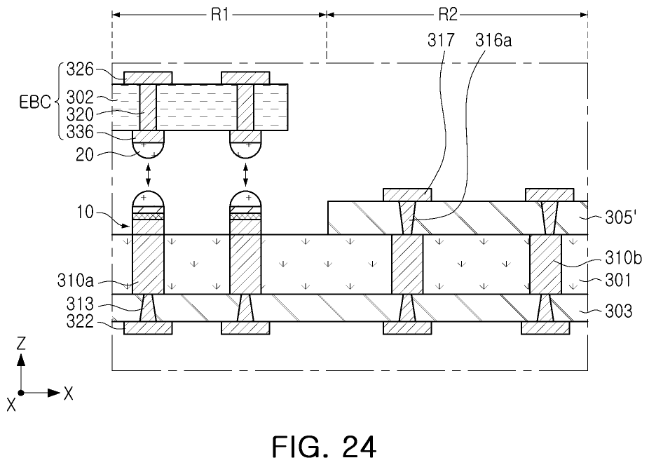

Referring to FIG. 24, the method may include an operation of disposing a preformed bridge structure EBC on the first through-electrodes 310a of the first region R1 and an operation of performing a reflow process for soldering first solder balls 10 formed on the first through-electrodes 310a and second solder balls 20 formed on lower surfaces of bridge lower pads 336 of the bridge structure EBC. The above first solder balls 10 can be formed according to a manufacturing method for a glass core layer 301 having an upper surface on which the first solder balls 10 are formed, as described above with reference to FIGS. 11 to 12B.

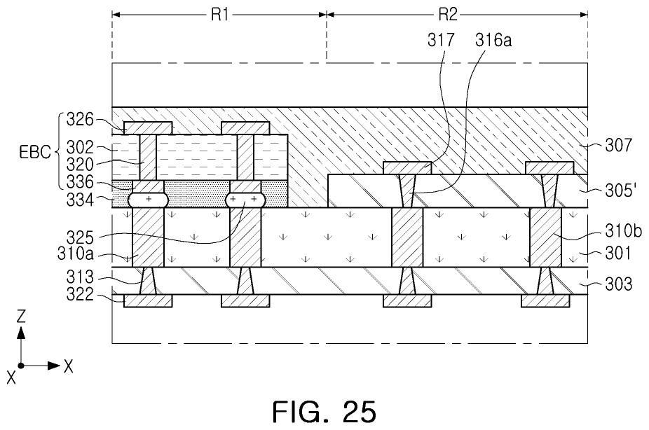

Referring to FIG. 25, bridge connection bumps 325 connecting the glass core layer 301 and the bridge structure EBC may be formed by combining the first solder balls 10 formed on the first through-electrodes 310a of the glass core layer 301 and the second solder balls 20 formed on the lower surface of the bridge lower pads 336 of the bridge structure EBC. The method may include an operation of forming a bridge mold layer 334 filling a space between the glass core layer 301 and the bridge structure EBC and covering side surfaces of the bridge connection bumps 325. After forming the bridge mold layer 334, a (2-2)-th upper insulating layer 307 covering the bridge structure EBC and the (2-1)-th upper insulating layer 305′ may be formed. The (2-2)-th upper insulating layer 307 may cover side and upper surface of the (2-1)-th upper insulating layer 305′, the first interconnection layers 317, and the bridge structure EBC.

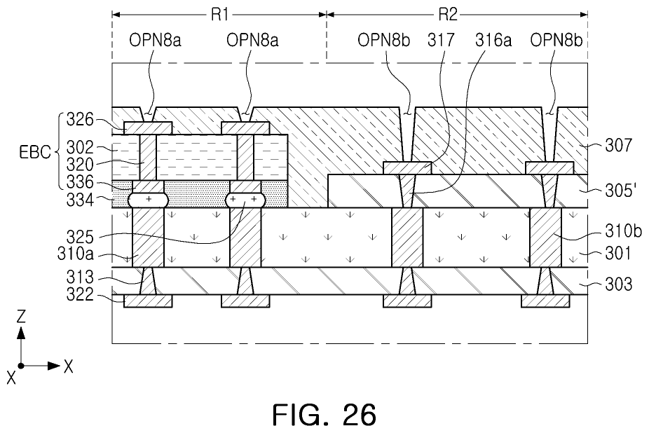

Referring to FIG. 26, in the first region R1, (8-1-th openings OPN8a may be formed to expose at least a portion of upper surfaces of the bridge upper pads 326 of the bridge structure EBC by penetrating through the (2-2)-th upper insulating layer 307, and in the second region R2, (8-2)-th openings OPN8b may be formed to expose at least a portion of upper surfaces of the first interconnection layers 317 by penetrating the (2-2)-th upper insulating layer 307.

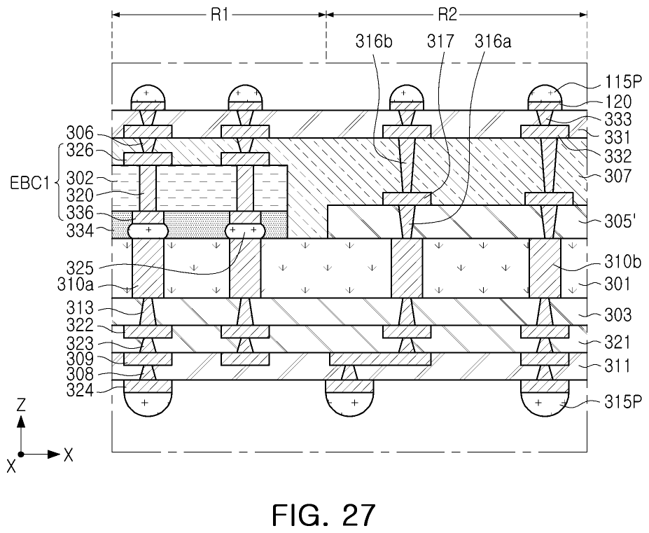

Referring to FIG. 27, in the first region R1, the (8-1-th openings OPN8a of FIG. 26 may be filled with a conductive material to form bridge vias 306, and in the second region R2, the (8-2)-th openings OPN8b of FIG. 26 may be filled with a conductive material to form second vias 316b. After forming the bridge vias 306 and the redistribution vias 316, third upper interconnection layers 332 connected to the bridge vias 306 and the redistribution vias 316 may be formed on the second upper insulating layer 305. After forming the third upper interconnection layers 332, a third upper insulating layer 331 may be formed, openings (not shown) may be formed so that upper surfaces of the third upper interconnection layers 332 are exposed, the openings may be filled with a conductive material to form third upper vias 333, fourth lower connection pads 120 may be formed on the third upper vias 333, and upper solder balls 115P may be formed on the fourth lower connection pads 120.

A third lower insulating layer 321 covering the third lower interconnection layer 322 may be formed on the lower surface of the second lower insulating layer 303, openings may be formed to expose lower surfaces of the third lower interconnection layer 322 by penetrating the third lower insulating layer 321, and the openings may be filled with a conductive material to form third lower vias 323.

Fourth lower interconnection layers 309 may be formed below the third lower vias 323. After forming the fourth lower interconnection layers 309, openings may be formed to expose lower surfaces of the fourth lower interconnection layers 309 by penetrating the fourth lower insulating layer 311, and then a conductive material may be filled to form fourth lower vias 308. Thereafter, third lower connection pads 324 may be formed on lower surfaces of the fourth lower vias 308, and lower solder balls 315P may be formed on lower surfaces of the third lower connection pads 324.

Next, referring to FIG. 5A, the package substrate 400 may be combined therewith through the lower solder balls 315P, and the semiconductor chips 100 and 200 may be combined therewith through the upper solder balls 115P. Accordingly, the semiconductor package 1000′ may be manufactured.

A semiconductor package according to embodiments of the present inventive concept may include a package substrate, an interposer structure disposed on the package substrate and including a glass core layer, and semiconductor chips on the interposer structure. Accordingly, the semiconductor package may reduce the cost by including a glass core layer having a relatively low cost. In addition, the interposer structure may include a bridge structure including a silicon substrate and a silicon through-electrode penetrating the silicon substrate, and the bridge structure may be connected to a glass through-via of the glass core layer through a bridge connection bump on the glass core layer. Accordingly, a semiconductor package having enhanced reliability may be provided as the performance of the semiconductor package is improved.

However, the benefits of the present inventive concept are not limited to the benefits described above, and may be expanded in various ways without departing from the spirit and scope of the present inventive concept.

While example embodiments have been shown and described above, it will be apparent to those skilled in the art that modifications and variations can be made to the embodiments without departing from the scope of the present inventive concept as defined by the appended claims.

What is claimed is:

1. A semiconductor package, comprising:
a package substrate comprising a first core layer and first core through-electrodes penetrating through the first core layer;
an interposer structure on the package substrate;
semiconductor chips on the interposer structure, and the semiconductor chips electrically connected to the package substrate through the interposer structure;
first connection bumps between the semiconductor chips and the interposer structure, and the first connection bumps electrically connecting the semiconductor chips and the interposer structure;
second connection bumps between the interposer structure and the package substrate, and the second connection bumps electrically connecting the interposer structure and the package substrate; and
third connection bumps below the package substrate,
wherein the interposer structure comprises:
a second core layer;
second core through-electrodes penetrating through the second core layer;
third core through-electrodes penetrating through the second core layer and spaced apart from the second core through-electrodes;
a bridge structure on the second core through-electrodes;
a redistribution structure on the third core through-electrodes; and
bridge connection bumps between the bridge structure and the second core through-electrodes,
wherein the bridge structure comprises a base substrate and bridge through-electrodes penetrating through the base substrate.

2. The semiconductor package of claim 1, wherein the bridge connection bumps are in contact with upper surfaces of the second core through-electrodes, respectively.

3. The semiconductor package of claim 1, further comprising:
a bridge mold layer filling a space between the bridge structure and the second core layer and covering side surfaces of the bridge connection bumps.

4. The semiconductor package of claim 3, further comprising:
an insulating structure covering side surfaces and upper surfaces of the base substrate of the bridge structure, a side surface of the bridge mold layer, and a side surface of the redistribution structure.

5. The semiconductor package of claim 4, wherein the redistribution structure comprises redistribution vias penetrating through the insulating structure and connected to the third core through-electrodes, respectively.

6. The semiconductor package of claim 5, further comprising:
bridge vias penetrating through the insulating structure and connected to the bridge structure,
wherein an upper surface of the insulating structure, upper surfaces of the bridge vias, and upper surfaces of the redistribution vias are coplanar with each other.

7. The semiconductor package of claim 1, further comprising:
a first insulating layer covering the third core through-electrodes on the second core layer; and
a second insulating layer covering side and upper surfaces of the first insulating layer and side and upper surfaces of the bridge structure,
wherein the first insulating layer comprises a first insulating material, and
the second insulating layer comprises a second insulating material different from the first insulating material.

8. The semiconductor package of claim 7, wherein an upper surface of the base substrate of the bridge structure is farther from the upper surface of the package substrate than the upper surface of the first insulating layer.

9. The semiconductor package of claim 7, wherein:
the redistribution structure comprises first vias penetrating through the first insulating layer and connected to the third core through-electrodes, respectively, first interconnection layers on the first vias and connected to the first vias, respectively, and second vias on the first interconnection layers; and
the second insulating layer covers side and upper surfaces of the first interconnection layers and side surfaces of the second vias.

10. The semiconductor package of claim 1, wherein:
the bridge structure further comprises:
bridge lower pads on a lower surface of the base substrate; and
bridge upper pads on an upper surface of the base substrate; and
wherein a width of each of the bridge lower pads is less than a width of each of the bridge upper pads.

11. The semiconductor package of claim 10, wherein:
each of the bridge connection bumps comprises a first conductive layer in contact with a respective second core through-electrode and a second conductive layer in contact with a respective bridge lower pad of the bridge structure;
the first conductive layer comprises a first conductive material;
the second conductive layer comprises a second conductive material different than the first conductive material; and
each of the second core through-electrodes has a diameter greater than a diameter of each of the bridge lower pads.

12. The semiconductor package of claim 1, wherein:
the second core layer of the interposer structure comprises a glass substrate; and
the base substrate of the bridge structure comprises a silicon substrate.

13. A semiconductor package, comprising:
a package substrate;
an interposer structure on the package substrate; and
semiconductor chips on the interposer structure, and the semiconductor chips electrically connected to the package substrate through the interposer structure,
wherein the interposer structure comprises:
a glass core layer;
first through-electrodes penetrating the glass core layer;
bridge structures on the first through-electrodes;
bridge connection bumps between the bridge structures and the first through-electrodes; and
bridge mold layers between the bridge structures and the glass core layer, and covering side surfaces of the bridge connection bumps,
wherein each of the bridge structures comprises a base substrate and bridge through-electrodes penetrating through the base substrate and each bridge through-electrode vertically overlapping a respective bridge connection bump.

14. The semiconductor package of claim 13, wherein the bridge connection bumps are each in contact with an upper surfaces of a respective first through-electrodes.

15. The semiconductor package of claim 13, wherein the interposer structure further comprises:
second through-electrodes penetrating through the glass core layer and horizontally spaced apart from the first through-electrodes;
upper interconnection structures on the second through-electrodes, respectively;
lower interconnection structures below the first through-electrodes and the second through-electrodes; and
an insulating structure covering side surfaces of the upper interconnection structures on the glass core layer.

16. The semiconductor package of claim 15, further comprising:
upper pads on an upper surface of the interposer structure, and upper pads of a first groups of the upper pads connected to a corresponding bridge structure and upper pads of a second group of the upper pads connected to corresponding upper interconnection structures;
lower pads on a lower surface of the interposer structure, and the lower pads connected to the lower interconnection structures, respectively;
first connection bumps between the upper pads and the semiconductor chips; and
second connection bumps between the lower pads and the package substrate.

17. The semiconductor package of claim 15, wherein:
the interposer structure further comprises bridge vias respectively connected to the bridge through-electrodes of a corresponding bridge structure, and the bridge vias are each disposed on the corresponding bridge structure;
the upper interconnection structures each comprise a first via on a respective second through-electrode, a first interconnection layer on the first via, and a second via on the first interconnection layer; and
upper surfaces of the bridge vias are coplanar with upper surfaces of the second vias.

18. The semiconductor package of claim 17, wherein:
the insulating structure comprises a first insulating layer surrounding side surfaces of the first vias on the second through-electrodes and a second insulating layer surrounding side and upper surfaces of the first interconnection layers and side surfaces of the second vias;
the first insulating layer comprises a first insulating material; and
the second insulating layer comprises a second insulating material different than the first insulating material.

19. A semiconductor package, comprising:
a package substrate;
an interposer structure on the package substrate; and
semiconductor chips on the interposer structure and electrically connected to the package substrate through the interposer structure,
wherein the interposer structure comprises:
a glass core layer;
first through-electrodes penetrating through the glass core layer;
second through-electrodes penetrating through the glass core layer and spaced apart from the first through-electrodes;
semiconductor interconnection dies with each semiconductor interconnection die disposed on corresponding first through-electrodes;
redistribution structures with each redistribution structure on corresponding second through-electrodes;
bridge connection bumps with each bridge bump between a corresponding semiconductor interconnection die and a corresponding first through-electrode; and
bridge mold layers with each bridge mold layer between a corresponding semiconductor interconnection die and the glass core layer and covering side surfaces of corresponding bridge connection bumps,
each of the semiconductor interconnection dies comprises:
a base substrate;
bridge through-electrodes penetrating through the base substrate and each bridge through-electrode vertically overlapping a respective bridge connection bump;
bridge upper pads with each bridge upper pad on a respective bridge through-electrodes; and
bridge lower pads with each bridge lower pad below a respective bridge through-electrodes, and
each of the bridge connection bumps are on a lower surface of a respective lower pad and an upper surface of a respective first through-electrode.

20. The semiconductor package of claim 19, wherein:
the semiconductor chips comprise a first semiconductor chip and a second semiconductor chip spaced apart from the first semiconductor chip, and
the semiconductor interconnection dies comprise a first semiconductor interconnection die vertically overlapping with the first semiconductor chip and a second semiconductor interconnection die vertically overlapping with the second semiconductor chip.
